(19) United States
(12) Patent Application Publication
(10) Pub. No.: US 2007/0257261 A1
(43) Pub. Date: Nov. 8, 2007

(54) METHOD FOR FORMING METAL WIRING, METHOD FOR MANUFACTURING ACTIVE MATRIX SUBSTRATE, DEVICE, ELECTRO-OPTICAL DEVICE, AND ELECTRONIC APPRATUS

(75) Inventors: Toshimitsu HIRAI, Chino (JP); Katsuyuki MORIYA, Azumino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/741,925

(22) Filed: Apr. 30, 2007

(30) Foreign Application Priority Data
May 2, 2006 (JP) 2006-128160

(51) Int. Cl. H01L 29/04; H01L 29/10; H01L 21/82; H01L 31/00

(52) U.S. Cl. 257/59; 438/129

(57) ABSTRACT

A device includes a substrate; a bank provided on the substrate; and a metal wiring in a wiring forming region of the substrate that is sectioned by the bank with a liquid phase method. The metal wiring includes a first film formed along a bottom of the wiring forming region and a side face of the bank facing the wiring forming region. The metal wiring also includes a second film disposed on the first film.

### RELATED APPLICATIONS

This application claims priority to Japanese Patent Application No. 2006-128160 filed May 2, 2006 which is hereby expressly incorporated by reference herein in its entirety.

### BACKGROUND

1. Technical Field

The present invention relates to a method for forming a metal wiring, a method for manufacturing an active matrix substrate, a device, an electro-optical device, and electronic apparatus.

2. Related Art

In recent years, liquid discharging methods have been increasingly used as coating techniques for manufacturing electronic devices. A liquid discharging coating technique generally involves discharging liquid in the form of droplets from a plurality of nozzles provided in a liquid discharging head while relatively moving a substrate and the liquid discharging head so as to repeatedly deposit the droplets on the substrate, and thus form a coated film. This technique has advantages in that less liquid is wasted and patterns can be directly coated (formed) without using additional techniques such as photolithography. For example, JP-A-11-274671 discloses a technique for forming a fine wiring pattern. According to this technique, a functional liquid containing a pattern forming material is discharged onto a substrate from a droplet discharging head to dispose (coat) the material on a pattern forming surface thereby providing the fine wiring pattern such as for a semiconductor integrated circuit.

JP-A-2003-315813 proposes a modified technique in which an intermediate layer is formed when forming a film pattern such as a wiring pattern so as to enhance an adhesion force between the substrate and the film pattern.

However, the technique of JP-A-11-274671 has the following problems.

When a bank corresponding to a metal wiring is pre-formed and a functional liquid is discharged to a metal wiring forming region surrounded by the bank to form a metal wiring, a lyophobic property is generally imparted to the bank. In particular, a lyophobic property is imparted to the surface of the bank by performing a lyophobic treatment such as CF₄ plasma processing. This encourages droplets discharged on a surface of the bank to migrate to the wiring forming region. In this case, the side faces of the bank that face the wiring forming region are also provided with the lyophobic property due to the generation of a fluorine group. As such, the adhesion force of the metal wiring is insufficient even when an intermediate layer is provided as in the example in JP-A-2003-315813.

### SUMMARY

The present invention seeks to provide a method for forming a metal wiring, a method for manufacturing an active matrix substrate, a device, an electro-optical device, and an electronic apparatus. The method for forming a metal wiring can enhance an adhesion force of the metal wiring.

Aspects of the invention will be described below.

A device according to a first aspect of the invention includes: a substrate; a bank provided on the substrate; and a metal wiring formed in a wiring forming region of the substrate sectioned by the bank by a liquid phase method. The metal wiring includes a first film formed along a bottom of the wiring forming region and a side face of the bank facing the wiring forming region. The metal wiring also includes a second film disposed on the first film.

In this structure, it is preferable that the second film is a wiring body, and the first film is an intermediate layer which enhances an adhesion force between the second film and the bottom of the wiring forming region, and between the second film and the side face of the bank.

Therefore, the intermediate layer which enhances the adhesion force between the wiring body and the bottom of the wiring forming region is also formed on the side face of the bank facing the wiring forming region. As such, the intermediate layer not only enhances the adhesion force of the wiring body to the bottom of the wiring forming region but also to the side face of the bank.

Further, a third film which covers and protects the second film may be used.

The above structure can prevent a (electro-) migration phenomenon, dispersion, an anti-CVD property, and the like of the second film (the wiring body).

The side face of the bank may have a lyophilic property relative to a functional liquid including a forming material of the first film, and an upper face of the bank may have a lyophobic property relative to the functional liquid.

In this case, even if the functional liquid including a material for forming the first film lands on the upper surface of the bank when being applied, the functional liquid can be repelled and introduced into the wiring forming region. In addition, since the side face of the bank has a lyophilic property, the functional liquid favorably spreads on the side face. Therefore, the first film can be easily formed along the side face of the bank.

An electro-optical device may include the device mentioned above.

An electronic apparatus may include the electro-optical device mentioned above.

Therefore, a high quality electro-optical device and electronic apparatus in which the adhesion force of the wiring is enhanced can be obtained.

A method for forming a metal wiring according to a second aspect of the invention includes: giving a lyophilic property to a bottom of a wiring forming region which is sectioned by a bank formed on a substrate by liquid phase method, and to a side face of the bank facing the wiring forming region; forming a first film along the bottom of the wiring forming region and the side face of the bank facing the wiring forming region; and disposing a second film on the first film.

In this structure, it is preferable that the second film is a wiring body, and the first film is an intermediate layer which enhances an adhesion force between the second film and the bottom of the wiring forming region, and between the second film and the side face of the bank.

Therefore, in the method for forming a metal wiring, an intermediate layer (the first film) enhances the adhesion force between the wiring body (the second film) and the bottom of the wiring forming region. Further, since the intermediate layer is also formed on the side face of the bank facing the wiring forming region, the intermediate layer not only enhances the adhesion force of the wiring body to the bottom of the wiring forming region but also enhances the adhesion force of the wiring body to the side face of the bank.

A third film which covers and protects the second film may be formed on the second film.

The above structure can prevent a (electro-) migration phenomenon, dispersion, an anti-CVD property, and the like of the second film (the wiring body).

A method for manufacturing an active matrix substrate according to a third aspect of the invention includes: (a) forming a gate wiring on a substrate; (b) forming a gate insulating film on the gate wiring; (c) disposing a semiconductor layer on the gate insulation film; (d) forming a source electrode and a drain electrode on the gate insulating film; (e) disposing an insulating material on the source electrode and the drain electrode; and (f) forming a pixel electrode on the insulating material. The method for forming a metal wiring according to the first aspect of the invention may be used in at least one of steps (a), (d), and (f).

A method for manufacturing an active matrix substrate according to a fourth aspect of the invention includes: (a) forming a source electrode and a drain electrode on a substrate; (b) forming a semiconductor layer on the source electrode and the drain electrode; (c) forming a gate electrode on the semiconductor layer with a gate insulating film interposed between the gate electrode and the semiconductor layer; and (d) forming a pixel electrode so as to be coupled to the pixel electrode. The method for forming a metal wiring according to the first aspect of the invention may be used in at least one of steps (a), (c), and (d).

A method for manufacturing an active matrix substrate according to a fifth aspect of the invention includes: (a) forming a semiconductor layer on a substrate; (b) forming a gate electrode on the semiconductor layer with a gate insulating film interposed between the gate electrode and the semiconductor layer; (c) forming a source electrode so as to be coupled to a source region of the semiconductor layer through a first contact hole formed in the gate insulating film, and a drain electrode so as to be coupled to a drain region of the semiconductor layer through a second contact hole formed in the gate insulating film; and (d) forming a pixel electrode so as to be coupled to the pixel electrode. The method for forming a metal wiring according to the first aspect of the invention may be used in at least one of steps (b), (c), and (d).

Therefore, in the method for manufacturing an active matrix substrate according to the third, fourth and fifth aspects of the invention, the electrode may be formed by using the above method for forming a metal wiring, and thus a high quality active matrix substrate with a high adhesion force of the wiring may be provided.

### BRIEF DESCRIPTION OF THE DRAWINGS

The invention will be described with reference to the accompanying drawings, wherein like numbers reference like elements.

FIG. 1 is a perspective view schematically showing a droplet discharge device.

FIG. 2 is a sectional schematic view illustrating a principal to discharge a liquid material by a piezoelectric method.

FIG. 3 is a plan view schematically showing a part of a TFT array substrate.

FIG. 4 is a plan view illustrating a schematic structure of a bank structure.

FIGS. 5A and 5B are sectional side views showing a part of a TFT.

FIGS. 6A to 6D are schematic views for explaining a method for forming a bank.

FIG. 7 is a schematic showing a plasma treatment device.

FIGS. 8A to 8E are schematic views for explaining a method for forming a wiring pattern.

FIGS. 9A to 9D are schematic views for explaining a method for forming a wiring pattern.

FIGS. 10A to 10C are diagrams showing steps for forming a TFT.

FIGS. 11A to 11C are diagrams showing steps for forming a TFT.

FIG. 12 is a plan view showing a liquid crystal display viewed from an opposing substrate.

FIG. 13 is a sectional view along line H-H′ of FIG. 12.

FIG. 14 is an equivalent circuit schematic of a liquid crystal display.

FIG. 15 is a partially enlarged view of the liquid crystal display.

FIG. 16 is an exploded perspective view of a noncontact card medium.

FIGS. 17A to 17C are views of specific examples of electronic apparatuses.

FIG. 18 is a sectional view schematically showing an example of an active matrix substrate.

FIG. 19 is a sectional view schematically showing another example of an active matrix substrate.

### DETAILED DESCRIPTION

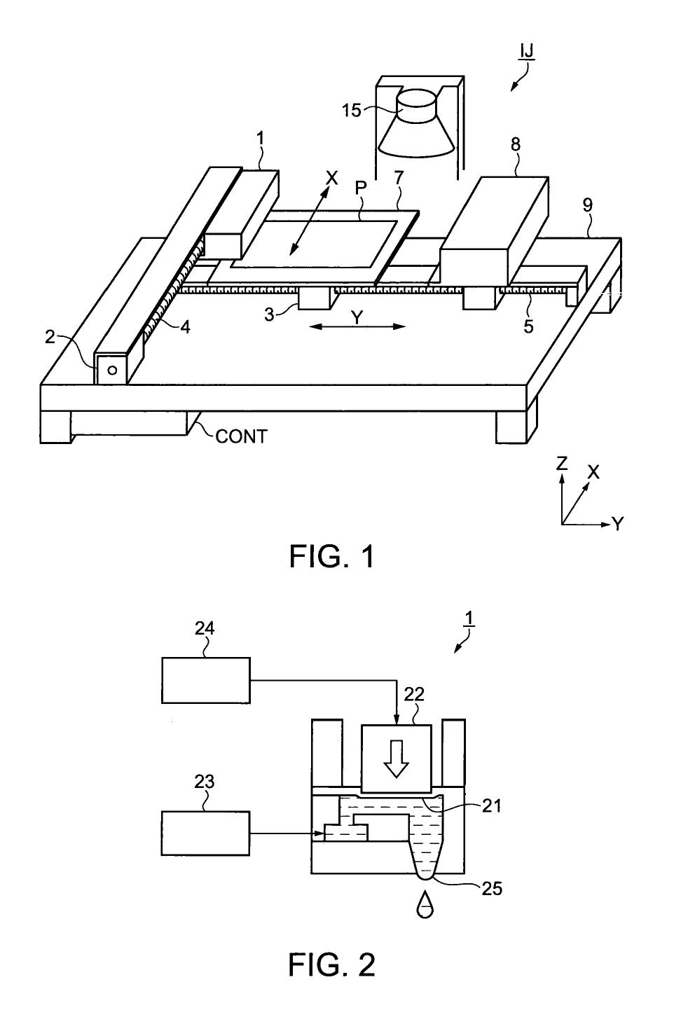

Embodiments of the present invention will be described below with reference to FIGS. 1 through 19.

Note that the scales of the members in the figures referred to herein are changed so that each can be adequately recognized.

### First Embodiment

A method for forming a metal wiring according to a first embodiment of the invention will be first described. Here, an ink (a functional liquid) for a wiring pattern (metal wiring) containing conductive particulates is discharged as droplets from a discharge nozzle of a droplet discharging head by a droplet discharging method so as to form a wiring pattern (a film pattern) in a recess within a bank formed on a substrate corresponding to the wiring pattern, that is, a region sectioned by the bank.

Here, the ink (functional liquid) for a wiring pattern mentioned above is composed of a dispersion liquid obtained by dispersing conductive particulates in a dispersion medium. In the embodiment, examples of the conductive particulates may include metal particulates containing at least one of gold, silver, copper, aluminum, chrome, manganese, molybdenum, titanium, palladium, tungsten, and nickel; their metal compounds; oxides; organic metal compounds; metal salt; and particulates of conductive polymers or a super-conductive material.

These conductive particulates can also be used with their surfaces coated with an organic matter in order to improve dispersibility. The diameter of the conductive particulates is preferably in the range from 1 nm to 0.1 μm. Particulates whose diameter is larger than 0.1 μm may cause clogging of the discharge nozzle included in the droplet discharging head, while particulates whose diameter is smaller than 1 nm may make the volume ratio of the coating to the particulates become so large that the ratio of the organic matter in the film becomes excessive.

Here, any dispersion medium that is capable of dispersing the above-described conductive particulates and does not cause an aggregation can be used. Examples of the medium may include: water; alcohols such as methanol, ethanol, propanol, and butanol; hydro-carbon compounds such as n-heptane, n-octane, decane, dodecane, tetradecane, toluene, xylene, cymene, durene, indene, dipentene, tetrahydronaphthalene, decahydronaphthalene, and cyclohexylbenzene; ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis (2-methoxyethyl) ether, and p-dioxane; and polar compounds such as propylene carbonate, gamma-butyrolactone, N-methyl-2-pyrrolidone, dimethylformamide, dimethyl sulfoxide, and cyclohexanone. Water, alcohols, hydro-carbon compounds, and ether compounds are preferably used in terms of particulate dispersibility, dispersion-liquid stability, and applicability to droplet discharge. Among others, water and hydro-carbon compounds are more preferably used.

The surface tension of the dispersion liquid of the conductive particulates is preferably within the range from 0.02 N/m to 0.07 N/m inclusive. A surface tension less than 0.02 N/m for discharging ink by droplet discharge increases the ink's wettability relative to a nozzle surface, so that a flying curve may possibly occur. A surface tension more than 0.07 N/m makes a meniscus shape at the tip of the nozzle unstable, making it difficult to control the amount and timing of discharge. In order to adjust the surface tension, a fluorine-, silicone- or nonionic-based surface tension adjuster, for example, may be added to the dispersion liquid in an amount small enough not to largely lower an angle of contact with a substrate. The nonionic-based surface tension adjuster enhances the wettability of an ink with respect to a substrate, improves film leveling, and prevents minute film-surface roughness. The surface tension adjuster may include, as necessary, organic compounds such as alcohol, ether, ester, ketone, and the like.

The viscosity of the dispersion liquid is preferably from 1 mPa·s to 50 mPa·s inclusive. A viscosity lower than 1 mPa·s for discharging droplets of the ink by droplet discharge may contaminate the periphery of the nozzle due to ink leakage. A viscosity higher than 50 mPa·s may possibly cause nozzle clogging, making it difficult to discharge droplets smoothly.

Examples of the substrate on which the wiring pattern is provided may include a glass or quartz-glass substrate, a silicon wafer, a plastic film and a metal plate. Above examples of the substrate may include a base layer such as a semiconductor film, a metal film, a dielectric film, or an organic film provided on the surface thereof.

Examples of the discharging technique of the droplet discharge may include a charge control, a pressurized vibration, an electromechanical conversion, an electrothermal conversion, and an electrostatic attraction. The charge control is a method to apply electric charges to a material with a charged electrode so as to discharge the material from a discharge nozzle while controlling its flying direction with a deflection electrode. Pressurized vibration is a method to discharge a material at a discharge nozzle tip by applying an extra-high voltage of approximately 30 kg/cm² to the material. If no control voltage is applied, the material goes straight ahead so as to be discharged from the discharge nozzle. If a control voltage is applied, the electrostatic repulsion within the material causes the dispersion of the material, thereby discharging no material from the discharge nozzle. Electromechanical conversion is a method that uses the deformation characteristic of piezoelectric elements in response to a pulsed electric signal. The method applies pressure to a space storing a material with an elastic material therebetween by deforming a piezoelectric element and pushes the material out of the space to discharge it from a discharge nozzle.

Electrothermal conversion is a method that evaporates a material rapidly with a heater provided in a space storing the material so as to produce bubbles, and discharges the material out of the space by the pressure of bubbles. Electrostatic attraction is a method that applies micro pressure to a space storing a material so as to form a meniscus of the material at a discharge nozzle, and applies electrostatic attraction so as to pull out the material. Other than these methods, a method that uses a fluid viscosity change caused by an electric field, and a method that uses electric discharge sparks can also be employed. Droplet discharging has an advantage of adequately disposing a material in a desired amount to a desired location with little waste of the material. An amount of one droplet of the liquid material (fluid) discharged by the droplet discharge is, for example, from 1 to 300 nanograms.

In the embodiment, a droplet discharge device (inkjet device) of the electromechanical conversion type using a piezo element (piezoelectric element) is used as the device discharging droplets.

FIG. 1 is a perspective view showing a schematic structure of a droplet discharge device IJ.

The droplet discharge device IJ includes a droplet discharging head 1, an X-axis direction drive axis 4, a Y-axis direction guide axis 5, a controller CONT, a stage 7, a cleaning mechanism 8, a base 9, and a heater 15.

The stage 7 holds a substrate P to be provided with liquid material (ink for a wiring pattern) by the droplet discharge device IJ, and therefore includes a fixing mechanism, which is not shown, for fixing the substrate P on a reference position.

The droplet discharging head 1 is a multi-nozzle droplet discharging head including a plurality of discharge nozzles. The longitudinal direction of the head 1 corresponds to the X-axis direction. The plurality of discharge nozzles is disposed on a lower surface of the droplet discharging head 1 at constant intervals. From the discharge nozzles of the droplet discharging head 1, the ink containing conductive particulates is discharged to the substrate P held by the stage 7.

An X-axis direction drive motor 2 is connected to the X-axis direction drive axis 4. The X-axis direction drive motor 2 is a stepping motor, for example, and rotates the X-axis direction drive axis 4 when a driving signal in the X-axis direction is supplied by the controller CONT. When the X-axis direction drive axis 4 rotates, the droplet discharging head 1 moves in the X-axis direction.

The Y-axis direction guide axis 5 is fixed on the base 9 so that it does not move. The stage 7 is equipped with a Y-axis direction drive motor 3. The Y-axis direction drive motor 3 is a stepping motor, for example, and moves the stage 7 in the Y-axis direction when a driving signal in the Y-axis direction is supplied by the controller CONT.

The controller CONT supplies the droplet discharging head 1 with a voltage for controlling a droplet discharge. The controller CONT also supplies the X-axis direction drive motor 2 with a drive pulse signal for controlling the movement of the droplet discharging head 1 in the X-axis direction, and the Y-axis direction drive motor 3 with a drive pulse signal for controlling the movement of the stage 7 in the Y-axis direction.

The cleaning mechanism 8 cleans the droplet discharging head 1. The cleaning mechanism 8 is equipped with a Y-axis direction drive motor which is not shown. By driving the Y-axis direction drive motor, the cleaning mechanism 8 moves along the Y-axis direction guide axis 5. The controller CONT controls the movement of the cleaning mechanism 8, as well.

The heater 15 subjects the substrate P to heat treatment by lump annealing. The heater 15 evaporates and dries solvents contained in a liquid material applied on the substrate P. The controller CONT controls application and interruption of the power source of the heater 15, as well.

The droplet discharge device IJ discharges droplets to the substrate P while relatively scanning the droplet discharging head 1 and the stage 7 holding the substrate P.

FIG. 2 is a diagram for explaining a discharge principal of liquid material by a piezo method.

In FIG. 2, a piezo element 22 is disposed adjacent to a liquid chamber 21 storing a liquid material (functional liquid). The liquid material is supplied to the liquid chamber 21 through a liquid material supply system 23 including a material tank that stores the liquid material. The piezo element 22 is coupled to a driving circuit 24. A voltage is applied through this driving circuit 24 to the piezo element 22, thereby deforming the piezo element 22. Thus, the liquid chamber 21 is deformed to discharge the liquid material from a discharge nozzle 25. In this case, changing a value of applied voltage controls a strain amount of the piezo element 22. Further, changing a frequency of applied voltage controls a strain velocity of the piezo element 22. The droplet discharge device employing this piezo system applies no heat to a material, advantageously imposing less effect on a composition of the material.

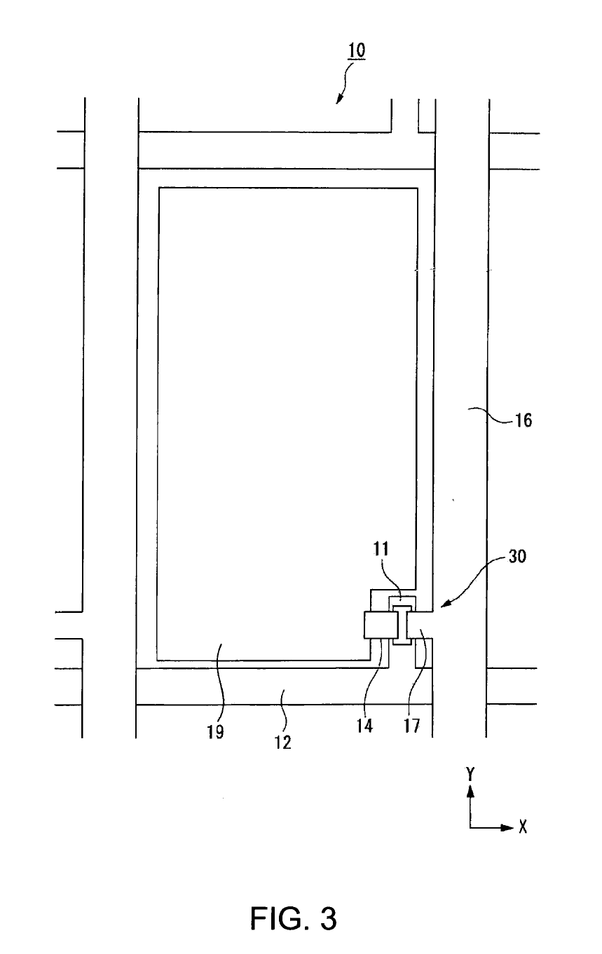

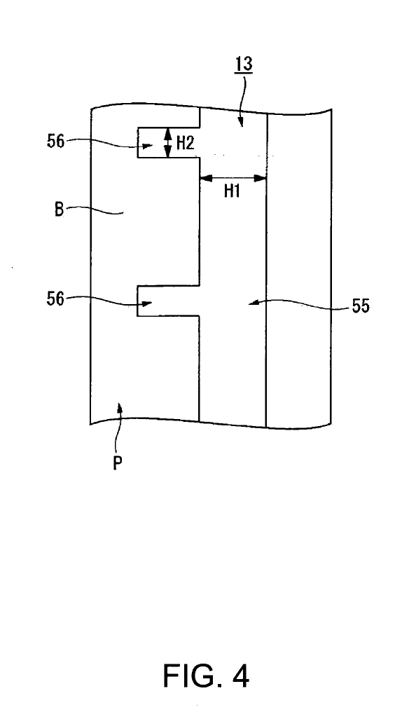

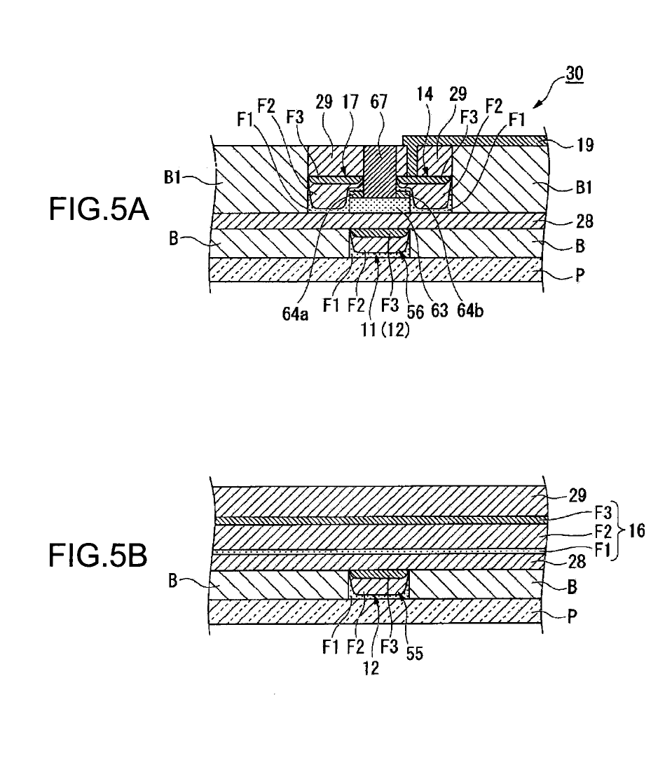

A thin film transistor (TFT) that is an example of a semiconductor device manufactured with the method for forming a wiring pattern of the embodiment will now be described. FIG. 3 is a plan view showing a schematic structure of part of a TFT array substrate including one TFT. FIG. 4 is a plan view showing a schematic structure of a bank structure. FIG. 5A is a sectional view of a TFT, and 5B is a sectional view of a part where a gate wiring and a source wiring intersect with each other.

Referring to FIG. 3, a gate wiring (metal wiring) 12, a source wiring 16, a drain electrode 14, and a pixel electrode 19 that is electrically coupled to the drain electrode 14 are provided on the TFT array substrate 10 including a TFT 30. The gate electrode 12 is provided to extend in the X-axis direction and part of it extends in the Y-axis direction. The part of the gate wiring 12 extending in the Y-axis direction is used as a gate electrode (metal wiring) 11. The width of the gate electrode 11 is smaller than the width of the gate wiring 12 as described later. The gate electrode 11 and the gate wiring 12 are formed in the method for forming a metal wiring of the embodiment. Part of the source wiring 16 extending in the Y-axis direction has a larger width, and is used as a source electrode 17.

As shown in FIG. 4, the bank structure of the embodiment is structured so that a bank B is formed on a substrate P. The region sectioned by the bank B is a wiring forming region 13 to be provided with the gate wiring 12 and the gate electrode 11 by disposing a functional liquid therein. The wiring forming region 13 is composed of a wiring forming region 55 which corresponds to the gate wiring 12 and a wiring forming region 56 which corresponds to the gate electrode 11. Here, “corresponds” means: a functional liquid disposed in the region 55 or the region 56 turns into a gate wiring 12 or a gate electrode 11 respectively by performing a curing treatment or the like.

Specifically, as shown in FIG. 4, the region 55 is provided to extend in the Y-axis direction of FIG. 3. The region 56 is provided approximately perpendicular to the region 55 (in the X-axis direction of FIG. 3) in a manner contacting (connected to) the region 55. In addition, the region 55 has a larger width than the region 56. In the embodiment, the region 55 is formed to have a width which is nearly equal to, or slightly larger than a flying diameter of a functional liquid discharged from the droplet discharge device IJ. Employing such a bank structure allows the functional liquid discharged on the region 55 to flow into the region 56 which is a fine pattern due to a capillary phenomenon.

The width of the region 55 is the length between the edges of the region 55 in the direction perpendicular to the direction in which the region 55 extends (the Y direction). Likewise, the width of the region 56 is the length between the edges of the region 56 in the direction perpendicular to the direction in which the region 56 extends (the X direction). As shown in FIG. 4, the width of the region 55 is H1, and the width of the region 56 is H2 which is smaller than H1.

As shown in FIGS. 5A and 5B, the gate wiring 12, the gate electrode 11 and the bank B are covered by an insulating film 28. An activation layer 63 that is a semiconductor layer, the source wiring 16, the source electrode 17, the drain electrode 14, and a bank B1 are provided on the insulating film 28. The activation layer 63 is provided in a position largely opposing the gate electrode 11. The part of the activation layer 63 opposing the gate electrode 11 is used as a channel region. Bonding layers 64a and 64b are provided on the activation layer 63. The source electrode 17 is bonded to the activation layer 63 with the bonding layer 64a therebetween, while the drain electrode 14 is bonded to the activation layer 63 with the bonding layer 64b therebetween. One combination of the source electrode 17 and the bonding layer 64a and the other combination of the drain electrode 14 and the bonding layer 64b are insulated from each other by a bank 67 provided on the activation layer 63. The gate wiring 12 is insulated from the source wiring 16 by the insulating film 28, while the gate electrode 11 is insulated from the source electrode 17 and the drain electrode 14 by the insulating film 28. The source wiring 16, the source electrode 17 and the drain electrode 14 are covered by an insulating film 29. Part of the insulating film 29, which covers the drain electrode 14, is provided with a contact hole. The pixel electrode 19 that is coupled to the drain electrode 14 through this contact hole is provided on the upper surface of the insulating film 29.

Further, as shown in FIGS. 5A and 5B, the gate wiring 12, the gate electrode 11, the source wiring 16, the source electrode 17, and the drain electrode 14 form a wiring pattern in a triple-layer structure in the embodiment.

In particular, in the embodiment, the gate wiring 12, the gate electrode 11, the source wiring 16, the source electrode 17, and the drain electrode 14 have a triple-layer structure arranged as a manganese layer (first layer) F1 as a base layer, a silver layer (second layer) F2 as a wiring body, and a nickel layer (third layer) F3 as a protection layer, from the bottom.

The manganese layer F1 as a base layer (intermediate layer) enhances the adhesiveness of the silver layer F2 to the substrate P, and is formed in an approximately U-shape along the bottom of the region 55 and the region 56 and the side faces of the bank B facing the regions 55 and 56. The silver layer F2 as a conductive layer is disposed and formed on the manganese layer F1. The nickel layer F3 as a thin film controls a (electro-) migration phenomenon and the like of the conductive film made of silver or copper, for example, and is formed to cover the silver layer F2.

Examples of material of the base layer F1 may include oxides of Ti, Cu, Ni, In, or Cr as well as manganese.

Examples of material of the protection layer F3 may include one or combination of metal materials selected from Ti, TiN, W, Mn, and the like as well as nickel.

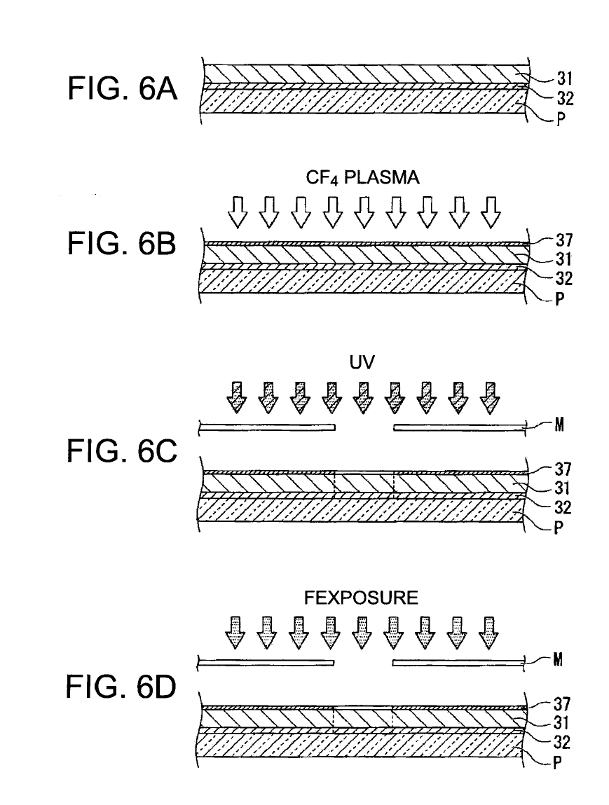

A process of forming a wiring pattern of the gate wiring 12 (the gate electrode 11) of the TFT 30 with the method for forming a metal wiring of the embodiment will now be described with reference to FIGS. 6 through 9.

In the embodiment, a glass substrate is provided with a bank corresponding to a wiring pattern as described above. Prior thereto, lyophilic treatment is performed to the substrate. The lyophilic treatment provides the substrate P with a good wettability to discharged ink in an after-mentioned arrangement by discharging an ink (functional liquid). As shown in FIG. 6A, for example, a surface of the substrate P is provided with a film 32 made of TiO₂ and the like and having a high lyophilic property (hydrophilic property). Otherwise, the film 32 having a high lyophilic property may be formed by depositing evaporated hexamethyldisilazane (HMDS) to a face to be treated of the substrate P (HMDS treatment). Or the surface of the substrate P may be roughened to be provided with a lyophilic property.

Bank Forming Process

After the lyophilic treatment is carried out, the substrate P is provided with a bank.

The bank functions as a partition member. The bank can be formed by any method such as lithography, printing, or the like. In lithography, a bank film 31 is formed by applying a resist liquid, which becomes a forming material of a lyophilic bank, to the substrate P at a predetermined height by a predetermined method such as spin-coating, spray-coating, roll-coating, dye-coating, dip-coating, and the like, as shown in FIG. 6. The resist liquid is a photosensitive material which, for example, includes any one of polysilazane, polysilane, or polysiloxane and any one of a photoacid generator or a photobase generator, and functions as a positive resist. In the embodiment, polysilazane liquid is used as a photosensitive material. The degree of the lyophilic property of the bank forming material is preferably such that a contact angle of the functional liquid is 20 degrees or less.

Here, the polysilazane liquid (resist liquid) to be a forming material of the bank primarily includes polysilazane. Especially, photosensitive polysilazane liquid including polysilazane and photoacid generators is preferably used. The embodiment uses this photosensitive polysilazane liquid. The photosensitive polysilazane liquid functions as a positive resist, and can be patterned directly by exposure and development treatments. Examples of such photosensitive polysilazane can include photosensitive polysilazane described in JP-A-2002-72504. Further, the photoacid generator included to the photosensitive polysilazane described in JP-A-2002-72504 can also be used. A photosensitive material such as a photosensitive polysilazane liquid and the like may include photobase generator instead of photoacid generator.

If polysilazane is, for example, polymethylsilazane expressed in Formula 1, polymethylsilazane is hydrolyzed partially as expressed in Formula 2 or 3 when humidified as mentioned later, and condensed to be polymethilsiloxane: —(SiCH₃O_{1.5})n-, as expressed in Formulas 4 through 6 when further heated at less than 400 degrees Celsius. Here, in Formulas 2 through 6, the formulas are simplified to show only a basic constituent unit (repeating unit) in a compound in order to explain the reaction mechanism.

Polymethylsiloxane formed as this has a polysiloxane skeleton having a methyl group on a side chain thereof. Therefore, the skeleton being a primary constituent is inorganic, having high resistance to heat treatment. Thus, polymethylsiloxane is preferable as a bank material.

—(SiCH₃(NH)_{1.5})n- Formula 1

SiCH₃(NH)_{1.5}+H₂O→SiCH₃(NH)(OH)+0.5NH₃ Formula 2

SiCH₃(NH)_{1.5}+2H₂O→SiCH₃(NH)0.5(OH)₂+NH₃ Formula 3

SiCH₃(NH)(OH)+SiCH₃(NH)(OH)+H₂O→2SiCH₃O_{1.5}+2NH₃ Formula 4

SiCH₃(NH)(OH)+SiCH₃(NH)0.5(OH)₂→2SiCH₃O_{1.5}+1.5NH₃ Formula 5

SiCH₃(NH)0.5(OH)₂+SiCH₃(NH)0.5(OH)₂→2SiCH₃O_{1.5}+NH₃+H₂O Formula 6

Next, the bank film 31 which is obtained is pre-baked on a hotplate at 110 degrees Celsius for about three minutes, for example.

After that, the bank film 31 is subjected to lyophobic treatment to make its surface lyophobic. As the lyophobic treatment, plasma treatment (CF₄ plasma treatment) using tetrafluoromethane as a lyophobic process gas is preferably employed. The CF₄ plasma treatment is carried out, for example, under the following condition: plasma power from 50 to 1000 W, a volume of tetrafluoromethane gas flow from 50 to 100 mL/min, a velocity of substrate transportation with respect to a plasma discharge electrode from 0.5 to 1020.0 mm/sec, and a substrate temperature from 70 to 90 degrees Celsius. The process gas is not limited to tetrafluoromethane, and other fluorocarbon gases, SF₆ and SF₅CF₃ can also be used.

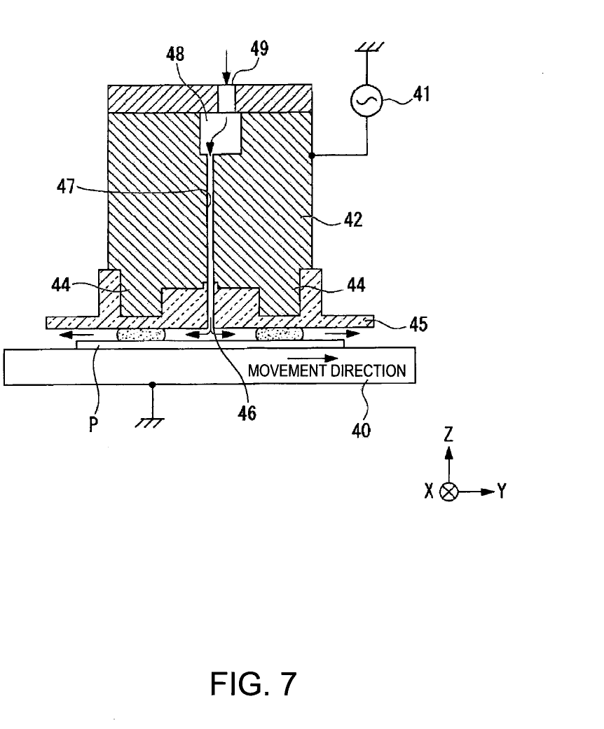

FIG. 7 is a schematic showing an example of a plasma treatment device used for CF₄ plasma treatment. The plasma treatment device shown in FIG. 7 includes an electrode 42 coupled to an alternating current power source 41, and a sample table 40. The sample table 40 can move in the Y-axis direction while supporting the substrate P which is a sample. Two electrical discharge generators 44, 44 parallel to each other and extending in the X-axis direction, which is orthogonal to the Y-axis direction are provided to the lower surface of the electrode 42, and a dielectric member 45 is provided so as to surround each electrical discharge generator 44. The dielectric member 45 prevents an abnormal discharge of the electrical discharge generator 44. The lower surface of the electrode 42 including the dielectric member 45 is almost planar. There is a small space (discharge gap) between a combination of the electrical discharge generator 44 and the dielectric member 45, and the substrate P. At a central portion of the electrode 42, a gas vent 46 included in a process gas supply part that is elongated in the X-axis direction is provided. The gas vent 46 is coupled to a gas inlet 49 via a gas passageway 47 and an intermediate chamber 48 inside the electrode.

A predetermined gas including the process gas ejected from the gas vent 46 via the gas passageway 47 flows inside the space in or against the movement direction (i.e. the Y-axis direction) and is exhausted outside from the front and rear ends of the dielectric member 45. At the same time, a predetermined voltage is applied from the alternating current power source 41 to the electrode 42, causing a gaseous discharge between the electrical discharge generators 44, 44 and the sample table 40. Plasma generated by this gaseous discharge produces excitation active species of the predetermined gas. Therefore, the whole surface of the bank film 31 provided on the substrate P that passes a discharge area is sequentially treated.

The predetermined gas is a mixture of tetrafluoromethane which is the process gas, and a rare gas such as helium (He) and argon (Ar), or an inert gas such as nitrogen (N₂) to make an electrical discharge under a pressure near atmospheric pressure start easily and be stably maintained.

Such lyophobic treatment is performed, and accordingly a fluorine group is introduced into the methyl group of polymethylsilazane constituting the bank film 31. Therefore, the surface of the bank film 31 is provided with high lyophobic property to the functional liquid, obtaining a lyophobic treatment layer 37 thereon, as shown in FIG. 6B. The degree of the lyophobic property of the lyophobic treatment layer 37 is preferably such that a contact angle of the functional liquid is 50 degrees or more. If the contact angle is less than 50 degrees, the functional liquid tends to remain on the upper surface of the bank B to be obtained.

Subsequently, as shown in FIG. 6C, the bank film 31 is selectively irradiated with ultraviolet rays by using a mask M so as to reduce the lyophobic property of the lyophobic treatment layer 37 on an irradiated part. The part which is selectively irradiated with ultraviolet rays by using the mask M corresponds to a part to be a wiring forming region of a wiring pattern (metal wiring), that is, a part to be removed by development treatment described later. Irradiated ultraviolet rays preferably used are rays in a short wavelength region as 172 nm, 185 nm, or 254 nm. The embodiment uses excimer ultraviolet rays for a selective irradiation with the mask M. The fluorine group introduced in the above lyophobic treatment desorbs due to the UV irradiation and the like, losing or sharply reducing its lyophobic property. Accordingly, the lyophobic property of the lyophobic treatment layer 37 hardly works on the UV irradiated part.

The bank film 31 is next exposed by using the above mask M, as shown in FIG. 6D. Since the bank film 31 functions as a positive resist as mentioned above, the part selectively exposed by using the mask M is removed by the following development treatment. Depending on a composition or photosensitive property of the photosensitive polysilazane liquid mentioned above, any exposure light source may be adequately selected and used from the following light sources which are conventionally used for an exposure of a photo-resist; a high pressure mercury lamp, a low pressure mercury lamp, a metal halide lamp, a xenon lamp, excimer laser, X-rays, electron rays, and the like. The energy amount of the irradiation is usually 0.05 mJ/cm² or more, more preferably 0.1 mJ/cm² or more, though depending on the light source or the film thickness as well. The irradiation amount has no uppermost limit, but it is not practical to be set too large. Commonly it is 10000 mJ/cm² or less. The embodiment sets the energy amount at 40 mJ/cm². The exposure can be performed in an ambient atmosphere (in the air) or a nitrogen atmosphere, but an oxygen-enriched atmosphere may be employed in order to promote the decomposition of polysilazane.

In the bank film 31 made of photosensitive polysilazane including photoacid generator, especially in the irradiated part of the film, such exposure treatment selectively generates acid, cleaving Si—N bond of polysilazane. Then, the bank film 31 reacts with moisture in the atmosphere, and is partially hydrolyzed, generating silanol (Si—OH) bond and decomposing polysilazane, as shown in Formula 2 or 3.

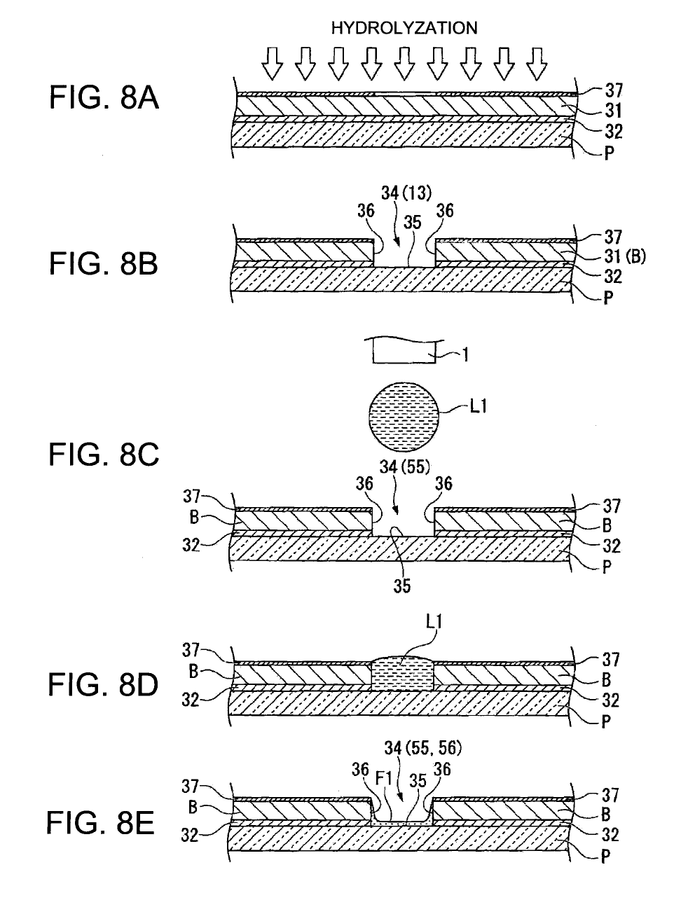

In order to promote further generation of such silanol (Si—OH) bond and decomposition of polysilazane, the bank film 31 which is exposed is hydrolyzed for five minutes, as shown in FIG. 8A, under the following condition; temperature 25 degrees Celsius, and relative humidity 85%, for example. If humidity is continuously supplied into the bank film 31 as this, acid which has contributed to a cleavage of Si—N bond repeatedly works as a cleavage catalyst. This Si—OH bond is generated in the exposure, but hydrolyzing the irradiated film after exposure more promotes generation of Si—OH in polysilazane.

Higher humidity in the treatment atmosphere in such hydrolysis treatment brings higher velocity of generation of Si—OH. However, when humidity is too high, vapor may condense on the surface of the film. Accordingly, it is practical that the relative humidity is 90% or less. Such hydrolysis treatment can be performed by allowing a moisture-containing gas to contact the bank film 31. That is, the treatment disposes the substrate P which is exposed in the hydrolysis treatment device and continuously introduces the moisture-containing gas into the device. Otherwise, the substrate P which is exposed may be put and left for a desired time in the hydrolysis treatment device in which the moisture-containing gas is introduced and the degree of humidity is controlled in advance.

Next, the bank film 31 hydrolyzed by tetraammonium hydroxide (TMAH) liquid having 2.38% concentration, for example, is developed at 28 degrees Celsius for about one minute, selectively removing the exposed part. Here, since the lyophobic property of a part to be developed, i.e. an exposed part is reduced by irradiating with ultraviolet rays in advance, the developer can easily penetrate into a face of the part to be removed. Therefore, the part to be removed is surely removed by the development, and enables the bank film 31 to have a desired bank shape, as shown in FIG. 8B. This forms banks B, B which section a forming region of the desired wiring pattern (film pattern), and a groove-like recess 34 (wiring forming region 13) which corresponds to the wiring pattern at the same time. The recess 34 corresponds to the wiring forming region 13 (wiring forming regions 55 and 56) shown in FIG. 4.

Examples of the developers may include alkali developers other than TMAH such as choline, sodium silicate, sodium hydroxide, potassium hydroxide.

The procedure of patterning the bank film 31 is not limited to the above using the photosensitive material. The bank film 31 may be patterned in the following procedure: forming a resist layer on the bank film 31, developing the resist layer by photolithography, and etching it.

Next, residue between the banks B, B which are obtained is removed by residue treatment, after rinsing by pure water as necessary. Examples of residue treatment may include hydrofluoric acid treatment performed by etching a residue part by hydrofluoric acid, ultraviolet ray (LV) irradiation treatment performed by irradiating ultraviolet rays, and O₂ plasma treatment performed by using oxygen as process gas in the atmosphere. The embodiment employs hydrofluoric acid treatment performed by contacting with hydrofluoric acid aqueous solution having 0.2% concentration for about 20 seconds, for example. In such residue treatment, since the banks B, B work as a mask, a bottom 35 of the recess 34 revealed between the banks B, B is selectively etched, removing remaining bank material and the like.

Glass or quartz glass used as the substrate P has a lyophilic property to the functional liquid. Therefore, the bottom 35 where the substrate P is revealed has a lyophilic property to the functional liquid.

A lyophobic treatment layer 37 is provided on the upper surfaces of the banks B, B, so that the upper surfaces of the banks B, B are lyophobic to the functional liquid. In contrast, side faces 36, facing the recess 34, of the bank B have a lyophilic property to the functional liquid, since the material for forming the bank B with a lyophilic property to the functional liquid is revealed there. Accordingly, the recess 34 is formed by the bottom 35 and the side faces 36 which have a lyophilic property to the functional liquid.

Next, as shown in FIG. 8C, droplets of a wiring patterning ink (functional liquid) are discharged to be disposed on the substrate P revealed in the recess 34 which is disposed between the banks B, B, by using the droplet discharge device IJ. Here, it is difficult to dispose the functional liquid directly on the wiring forming region 56 which is a fine wiring pattern, as shown in FIG. 4. Therefore, the functional liquid is disposed on the wiring forming region 55 so that it flows into the wiring forming region 56 by way of the capillary phenomenon.

First, a functional liquid L1 for forming a manganese layer F1 is discharged to the wiring forming region 55 by the droplet discharge device IJ. The functional liquid L1 is obtained by dispersing manganese (Mn) as conductive particulates in an organic disperse medium. The functional liquid La disposed on the wiring forming region 55 by the droplet discharge device IJ spreads on the wiring forming region 55. Even if the functional liquid L1 lands on the upper surface of the bank B, the functional liquid L is repelled to flow into the region 55 since the upper surface has a lyophobic property.

Further, since the side faces 36 have a lyophilic property, the functional liquid L1 which is discharged and disposed preferably flows over the entire wiring forming region 13. Therefore, the functional liquid L1 fills the region 55 and flows into the region 56, as shown in FIG. 8D.

After the functional liquid L1 is applied to the recess 34 (the wiring forming regions 55 and 56), the functional liquid L1 (manganese layer F1) is dried and fired so as to remove organic component of the disperse medium. The drying and firing treatments secure the electrical contact between the conductive particulates, turning the functional liquid L1 into a conductive film.

The drying treatment may be carried out by heating the substrate P with a common hot plate or electric furnace, for example. Here, this drying treatment especially for reducing unevenness of the film thickness is carried out at 120 degrees Celsius for two minutes. The temperature for the firing treatment is adequately determined in the light of the following: the boiling point (vapor pressure) of the dispersion medium; thermal behaviors such as dispersibility, oxidizability, and the like of the particulates; the presence and volume of a coating material; the heat resistance temperature of the base material, or the like. For example, removing a coating material made of organic matter requires heating at 220 degrees Celsius for 30 minutes.

Accordingly, the manganese layer F1 is formed in the recess 34 (on the wiring forming regions 55 and 56) as shown in FIG. 8E. Here, the bottom 35 of the recess 34 and the side face 36 of the bank B have a lyophilic property to be wet with the functional liquid L1 preferably, so that the manganese layer F1 after firing is formed in an approximately U-shape as cross-sectionally viewed in a manner covering the bottom 35 of the recess 34 and the side 36 of the bank B, as shown in the figure.

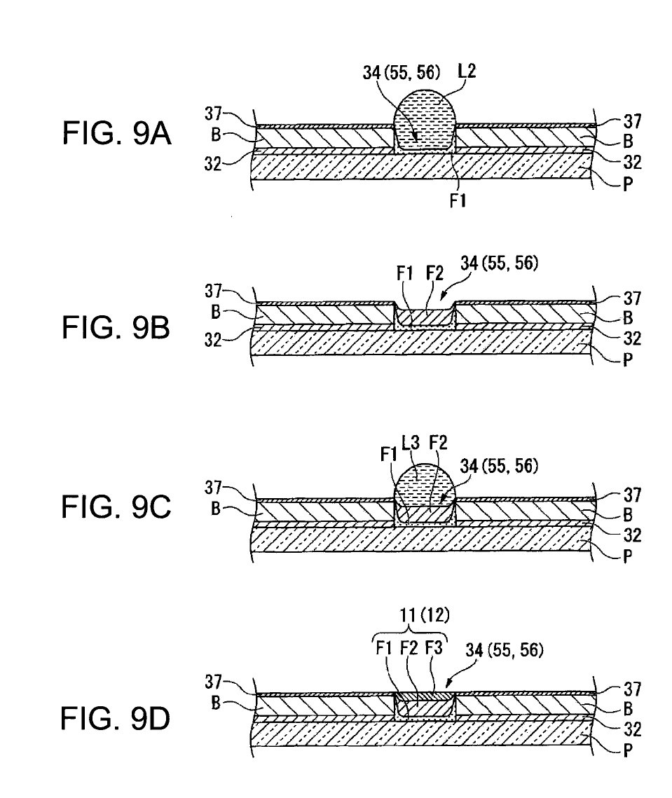

Droplets of functional liquid L2 are applied to the recess 34 (the wiring forming regions 55 and 56) provided with the manganese layer F1 so as to form a silver layer F2 as shown in FIG. 9A. The functional liquid L2 is obtained by dispersing silver (Ag) nanoparticles as conductive particulates in an organic disperse medium. Then, the functional liquid which is disposed is dried and fired so as to remove the disperse medium.

The firing treatment is performed as pre-firing first for removing the disperse medium (organic component) under air atmosphere, and firing second under nitrogen gas atmosphere. The pre-firing for oxidizing the organic component is preferably carried out at 130 degrees Celsius or higher temperature. Further, since particles of silver grow when heated under the circumstance including oxygen, the pre-firing is preferably carried out at 230 degrees Celsius or lower temperature so as to prevent particle growth. The embodiment carries out the pre-firing at 220 degrees Celsius for 30 minutes under air atmosphere. The firing is preferably carried out at the temperature from 230 to 350 degrees Celsius. The embodiment carries out the firing approximately at 300 degrees for 30 minutes under the nitrogen atmosphere. The embodiment carries out the firing under the nitrogen gas atmosphere, thereby preventing the particle growth.

This firing treatment forms the silver layer F2 of the wiring body disposed over the manganese layer F1 in a layered state as shown in FIG. 9B.

Subsequently, droplets of functional liquid L3 are applied and disposed over the silver layer F2 in the recess 34 (the wiring forming regions 55 and 56) so as to form a nickel layer F3 as shown in FIG. 9C. The functional liquid L3 is obtained by dispersing nickel as conductive particulates in an organic disperse medium. Then, the functional liquid which is disposed is dried and fired so as to remove the dispersion medium.

This treatment is performed as drying first at about 70 degrees Celsius for 10 minutes under air atmosphere so as to avoid uneven drying; pre-firing second at about 220 degrees Celsius for 30 minutes under air atmosphere so as to remove (oxidize) the dispersion medium (organic component) as the case of forming the silver layer F2; and then firing at about 300 degrees Celsius for 30 minutes under the nitrogen gas atmosphere so as to prevent the silver particle growth.

The drying and firing treatments form the nickel layer F3 as a protection layer disposed over the silver layer F2 in a layered state, forming the gate electrode 11 and the gate wiring 12 in the recess 34 (the wiring forming regions 55 and 56), as shown in FIG. 9D.

The above firing treatment allows the bank B, made of polysilazane in which SiOH is generated by the hydrolyzation and the exposure, to easily have SiOSi as shown in above Formulas 4 through 6, converting the bank B into a silica-ceramics film such as polymethiysiloxane having few or no SiNH bonds. Then, since the bank B made of polymethylsiloxane (silica-ceramics film) has the polysiloxane skeleton as mentioned above, it has high resistance to heating treatment, being able to sufficiently resist the firing treatment for the wiring pattern.

Subsequently, the entire surface, which is the surface including the bank B, of the substrate P is exposed. The exposure treatment condition is same as the one in the process shown in FIG. 6D. Such exposure over the entire surface exposes the bank B which has not been exposed in the previous exposure treatment. Polysilazane constituting the bank B partially hydrolyzes by the exposure, and consequently decomposes due to the generation of silanol (Si—OH) bond.

The above processes secure the electrical contact between the particulates, turning a dried film (wiring pattern) composed of the functional liquid after a discharge process into a conductive film, that is, the gate wiring 12 and the gate electrode 11 shown in FIGS. 3 and 5.

As above, the embodiment forms the manganese layer F1 which enhances the adhesion force of the silver layer F2 of the wiring body along the side face 36 of the bank B as well as the bottom 35 of the recess 34, and is able to substantially enhance the adhesion force of the gate electrode 11 and the gate wiring 12 to the substrate P. Accordingly, a superior TFT array substrate 10 in which metal wiring hardly disengages can be obtained.

In addition, the embodiment using the side face 36 with a lyophilic property can easily form the manganese layer F1 along the side face 36, and introduce the functional liquid from the wiring forming region 55 to the wiring forming region 56 smoothly, and is able to easily form the metal wiring with a fine width.

Further, the embodiment covers the silver layer F2 by the nickel layer F3 so as to prevent the migration phenomenon of the silver layer F2, and is able to provide the superior metal wiring.

Here, a resist liquid as a forming material of a bank is not limited to the photosensitive polysilazane liquid, used in the embodiment, including photoacid generator. Examples of the resist liquid may include polysilazane liquid other than the above polysilazane liquid, polysilane liquid, polysiloxane liquid, and common resist material (resist liquid) made of organic material.

In addition, in the embodiment, the hydrolysis treatment especially promotes the generation of silanol (Si—OH) bond and the decomposition of polysilazane, but is not limited to it. This hydrolysis treatment may be omitted depending on the kind of polysilazane liquid to be used, for example. Further, ultraviolet ray irradiate treatment (ultraviolet ray irradiate process) in FIG. 6C and the exposure treatment (exposure process) in FIG. 6D are carried out successively in this order in the embodiment, but this order may be inverted, that is the exposure treatment (exposure process) and the ultraviolet ray irradiate treatment (ultraviolet ray irradiate process) may be carried out in this order. The treatments can be carried out successively with one mask in such case as well, thereby improving productivity.

### Second Embodiment

A procedure of forming the TFT 30 on the substrate P provided with the gate wiring 12 and the gate electrode 11 will now be described.

The description in the second embodiment uses the droplet discharge method, the droplet discharge device, the semiconductor device to be manufactured, and the like which are essentially identical to the ones in the first embodiment.

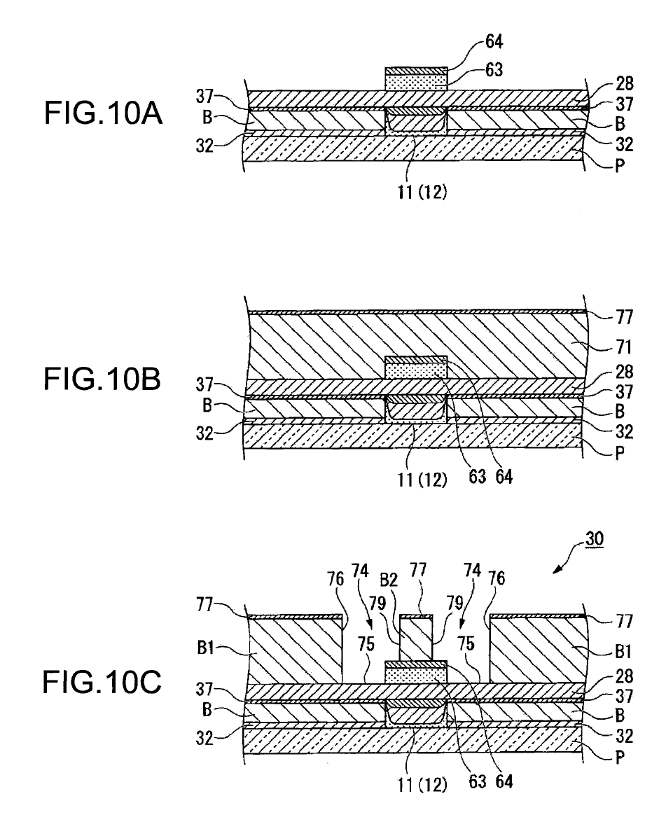

In the present embodiment, as shown in FIG. 10A, an insulating film 28 (a gate insulating film) and an activation layer 63 which is a semiconductor layer, a bonding layer 64 are successionally formed on the gate wiring 12 (the gate electrode 11) as a wiring pattern (metal wiring) formed in the first embodiment, by plasma CVD. A silicon nitride film is used for the insulating film 28, an amorphous silicon film for the activation layer 63, and an n+ silicon film for the bonding layer 64. Appropriate material gases and plasma conditions are adopted. In forming by CVD, the thermal history from 300 to 350 degrees Celsius is required. However, the bank B made of the material having polysiloxane skeleton which is inorganic has superior heat resistance, and is able to avoid problems with respect to heat resistance.

Then, material for forming a bank is disposed over the insulating film 28, the activation layer 63, and the bonding layer 64 so as to form a bank film 71 as shown in FIG. 10B. In the embodiment, the bank film 71 is formed by using the photosensitive polysilazane liquid in the first embodiment, though it is not limited.

Subsequently, after the bank film 71 which is obtained is pre-baked at 110 degrees Celsius for three minutes on a hot plate, for example, the bank film 71 is subjected to the lyophobic treatment like the first embodiment so as to form a lyophobic treatment layer 77 on the surface of the bank film 71.

After that, in order to pattern the bank film 71, the ultraviolet ray irradiation treatment (ultraviolet ray irradiation process) shown in FIG. 6C and the exposure treatment (exposure process) shown in FIG. 6D are performed successionally like the first embodiment. A desired part can be selectively treated by using one mask in this case as well.

After the hydrolysis treatment is performed as desired, the development treatment is performed so as to make the bank film 71 be a bank B1 and a bank B2 which have a desired bank shape, accordingly forming a groove-like recess 74 surrounded by the bank B1 and the bank B2, as shown in FIG. 10C. The recess 74 reveals the insulating film 28 on the bottom thereof, and parts of the activation layer 63 and the bonding layer 64. Here, since the lyophobic property of a part to be developed, i.e. an exposed part is reduced by irradiating with ultraviolet rays in advance, the developer can easily penetrate into a face of a part to be removed as the first embodiment. Thus, the part to be removed is surely removed by the development, and is able to form the bank B1 and the bank B2 having a desired shape as shown in FIG. 10C.

Next, residue between the banks B1 and B2 which are obtained is removed by residue treatment, after rinsing by pure water as necessary. Examples of residue treatment may include: hydrofluoric acid treatment performed by etching a residue part by hydrofluoric acid; ultraviolet ray (UV) irradiation treatment performed by irradiating with ultraviolet rays; and O₂ plasma treatment performed by using oxygen as process gas in the atmosphere.

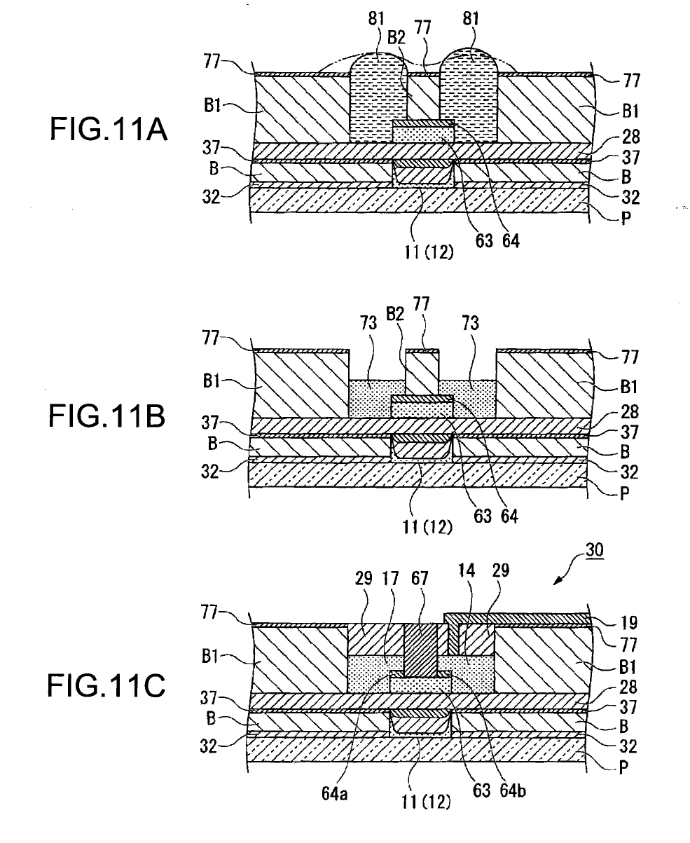

Subsequently, as shown in FIG. 11A, droplets of wiring pattern forming ink 81 are discharged and disposed between the bank B1 and the bank B2 like the process of the first embodiment shown in FIGS. 8C and 8D. This wiring pattern forming ink is, for example, same as the ink used when the gate wiring 12 and the gate electrode 11 are formed.

After that, the exposure and the firing treatments of the entire surface described in the first embodiment are carried out, making the banks B1 and B2 have polysiloxane skeleton. At the same time, as shown in FIG. 11B, a circuit wiring film 73 which is a wiring film forming a wiring pattern is formed. In the embodiment, the wiring pattern formed by this circuit wiring film 73 serves as the gate wiring 16, the gate electrode 17, and the drain electrode 14 shown in FIGS. 3 and 5.

Subsequently, the bank B2 is removed, and the bonding layer 64 is etched so as to separate into a bonding layer 64a that bonds the source electrode 17 and a bonding layer 64b that bonds the drain electrode 14. A bank 67 to insulate the source electrode 17 and the drain electrode 14 is provided in an area from which the bank B2 has been removed and an area from which the bonding layer 64 has been removed. Also, the insulating film 29 is provided so as to fill the groove 74 in which the source electrode 17 and the drain electrode 14 are provided. This process provides a flat upper surface made up of the bank B1, the bank 67, and the insulating film 29. Here, the bank 67 and the insulating film 29 may be made of the same material. In this case, it is possible to insulate the source electrode 17 and the drain electrode 14 by placing the insulating film 29 so as to fill the groove 74. Alternatively, before forming the bank film 71, the bonding layer 64 may be etched so as to separate into the bonding layer 64a that bonds the source electrode 17 and the bonding layer 64b that bonds the drain electrode 14.

Then a contact hole is provided to part, which covers the drain electrode 14, of the insulating film 29 which is disposed to fill the recess 74. A pixel electrode 19 made of indium tin oxide (ITO) that is coupled to the drain electrode 14 through this contact hole is provided on the upper surface of the insulating film 29.

The gate electrode 11 and the gate wiring 12 are formed as the first embodiment, and the source electrode 17 and the drain electrode 14 are formed as the present embodiment, being able to form the TFT 30 as the semiconductor device. Accordingly, a TFT array substrate 10 including a plurality of the TFTs 30 can be manufactured.

In such method for manufacturing the TFT 30 (semiconductor device), the TFT 30 has a wiring pattern (metal wiring) formed with superior adhesion, making the transistor property obtained by the wiring pattern stable. In addition, the fine wiring pattern can be achieved so as to realize the miniaturization of the TFT 30.

The circuit wiring film 73 (the source wiring 16, the source electrode 17, and the drain electrode 14) described in the embodiment may be provided with a base layer made of manganese and the like, and a protection layer made of nickel and the like as with the gate wiring 12 and the gate electrode 11 described in the first embodiment.

### Third Embodiment

Liquid Crystal Display

A liquid crystal display as an example of an electro-optical device according to a third embodiment of the invention will now be described. This liquid crystal display includes a TFT having a circuit wiring provided by the method for forming a wiring pattern (metal wiring) described in the first embodiment.

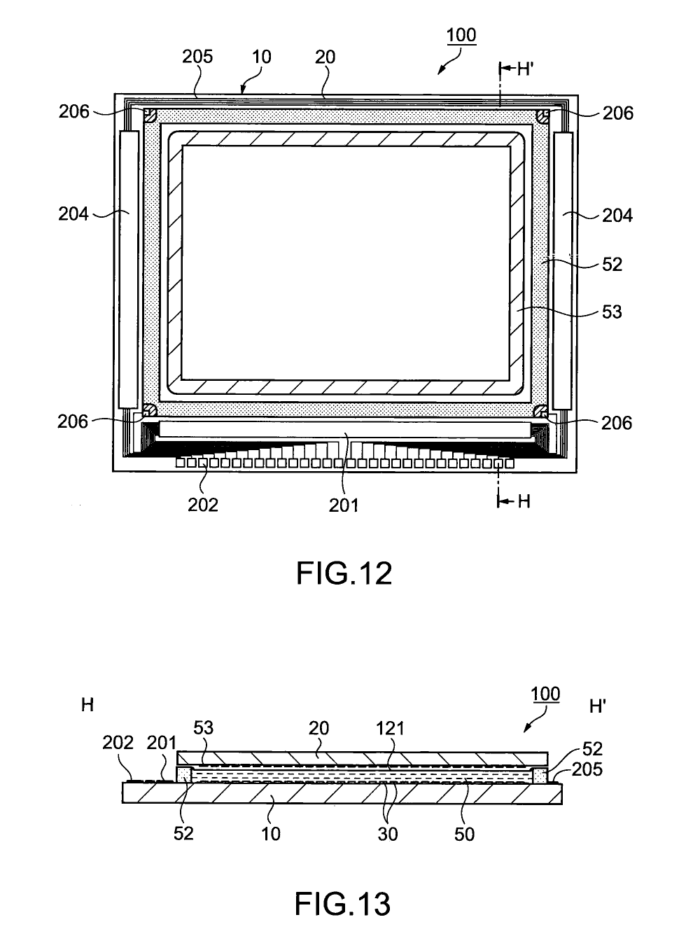

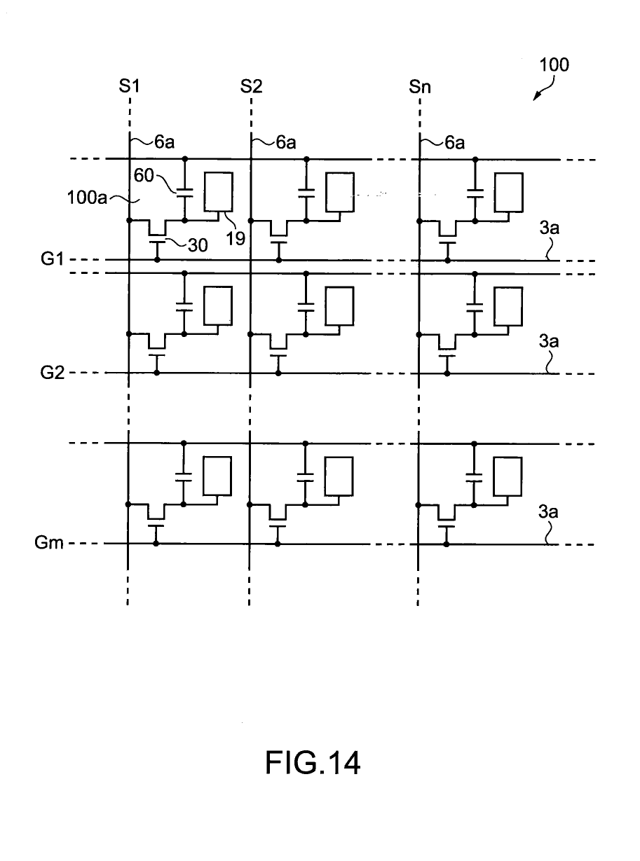

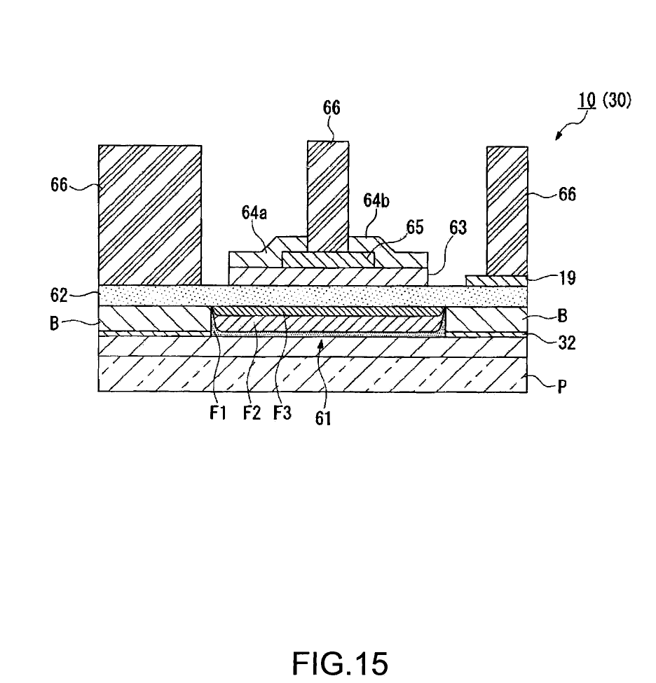

FIG. 12 is a plan view of the liquid crystal display according to the embodiment with each component viewed from an opposing substrate. FIG. 13 is a sectional view along line H-H′ of FIG. 12. FIG. 14 is an equivalent circuit view showing each element, wiring, etc. in a plurality of pixels arranged in a matrix in an image display area of the liquid crystal display. FIG. 15 is a partially enlarged view of the section of the liquid crystal display. It should be noted that different scales are used for the layers and members in the accompanying drawings, so that they can be recognized.

Referring to FIGS. 12 and 13, in a liquid crystal display (electro-optical device) 100 of the embodiment, a TFT array substrate 10 and an opposing substrate 20 are bonded as a pair with a photocuring sealant 52 interposed therebetween. In an area defined by the sealant 52, a liquid crystal 50 is sealed and retained. The sealant 52 is provided in a closed frame in an area included in the substrate surface.

In a region inside the area where the sealant 52 is provided, a peripheral light-blocking film 53 made of a light blocking material is provided. In an area outside the sealant 52, a data line driving circuit 201 and a mount terminal 202 are provided along one side of the TFT array substrate 10. Provided along two sides adjacent to the one side are scanning line driving circuits 204. Provided along another side of the TFT array substrate 10 are a plurality of wiring lines 205 to connect the scanning line driving circuits 204 provided to the both sides of an image display area. At one or more of the corners of the opposing substrate 20, an inter-substrate conductive material 206 is disposed to provide electrical conductivity between the TFT array substrate 10 and the counter substrate 20.

In this regard, instead of providing the data line driving circuit 201 and the scanning line driving circuits 204 on the TFT array substrate 10, a tape automated bonding (TAB) substrate on which a driving LSI is mounted, and a group of terminals provided around the TFT array substrate 10 may be electrically and mechanically connected with an anisotropic conductive film interposed therebetween. Note that a retardation film, a polarizer, and the like, included in the liquid crystal display 100 are aligned in a predetermined direction (not shown) depending on the type of the liquid crystal 50, that is, operation modes including twisted nematic (TN) and super twisted nematic (STN) modes and normally white and normally black modes. If the liquid crystal display 100 is provided as a color display, red (R), green (G) and blue (B) color filters, for example, and their protective films are provided in an area in the opposing substrate 20 opposing to each pixel electrode in the TFT array substrate 10 that is described below.

In the image display area of the liquid crystal display 100 having the above-described structure, as shown in FIG. 14, a plurality of pixels 100a are arranged in a matrix. Each of the pixels 100a is provided with a TFT (switching element) 30 for switching a pixel. To the source of the TFT 30, a data line 6a that supplies pixel signals S1 through Sn is electrically coupled. The pixel signals S1 through Sn to be written in the data line 6a may be supplied in this order or in groups for a plurality of adjacent data lines each corresponding to the data line 6a. A scanning line 3a is electrically coupled to the gate of the TFT 30. Scanning signals G1 through Gm are applied pulsatively and line-sequentially in this order at a predetermined timing to the scanning line 3a.

The pixel electrode 19 is electrically coupled to the drain of the TFT 30. The TFT 30, which is a switching element, is switched on for a certain period, writing the pixel signals S1 through Sn supplied from the data line 6a in each pixel at a predetermined timing. The pixel signals S1 through Sn, each of which has a predetermined level and written in liquid crystal through the pixel electrode 19, are retained between opposing electrodes 121 of the opposing substrate 20 shown in FIG. 13 for a certain period. In order to prevent a leak of the retained pixel signals S1 through Sn, a storage capacitor 60 is provided in parallel with a liquid crystal capacitor formed between the pixel electrode 19 and the opposing electrode 121. For example, the voltage of the pixel electrode 19 is retained by the storage capacitor 60 for a period of time three orders of magnitude longer than the time for which a source electrode is applied. Consequently, an electron retention property improves, and is able to provide the liquid crystal display 100 with a high contrast ratio.

FIG. 15 is a partially enlarged sectional view of the liquid crystal display 100 including the TFT 30 of bottom-gate structure. On the substrate P made of glass included in the TFT array substrate 10, a gate wiring (metal wiring) 61 composed of the manganese layer F1, the silver layer F2, and the nickel layer F3 is provided between banks B, B on the glass substrate P by the method for forming a metal wiring of the firs t embodiment.

On the gate wiring 61, the activation layer 63 that is a semiconductor layer made of an amorphous silicon (a-Si) layer is provided with a gate insulating film 62 made of SiNx therebetween. Part of the activation layer 63 facing this gate wiring area serves as a channel region. On the activation layer 63, the bonding layers 64a and 64b made of n+ a-Si layers, for example, are disposed in order to provide ohmic bonding. On a central portion of the activation layer 63 serving as the channel region, an insulating etch stop film 65 made of SiNx is provided so as to protect the channel. The gate insulating film 62, the activation layer 63, and the etch stop film 65 are patterned as shown, after CVD, by resist application, exposure to light and development, and photoetching.

Furthermore, the bonding layers 64a and 64b and the pixel electrode 19 made of ITO are also formed and patterned as shown by photoetching. On the pixel electrode 19, the gate insulating film 62, and the etch stop film 65, banks 66 are projectingly provided. Between the banks 66, source lines and drain lines are formed by discharging silver compound droplets with the above-described droplet discharge device IJ.

While the TFT 30 which is an example of the device of the embodiment of the invention serves as a switching element to drive the liquid crystal display 100, it is also applicable for organic electroluminescent (EL) displays, for example. An EL display is an element in which a thin film containing fluorescent inorganic and organic compounds are sandwiched between a cathode and anode. By injecting electrons and holes into the thin film to recombine them and thus generate excitons, the element emits light by means of light emission (fluorescence/phosphorescence) as the excitons get deactivated. Among fluorescent materials used for an EL display element, materials exhibiting luminescent colors of red, green and blue, that is, materials for forming a light-emitting layer and a hole injection/electron transport layer are used as ink. The materials are patterned on a substrate including the TFT 30 so as to manufacture a light-emitting full color EL device. A range of the electro-optical device according to the embodiment of the invention includes such organic EL devices.

The electro-optical device of the embodiment is also applicable to plasma display panels (PDP) and surface-conduction electron emitters that uses a phenomenon of emitting electrons by passing an electrical current through a small thin film on a substrate in parallel with the surface of the film.

Such an electro-optical device is provided with a semiconductor device which realizes high quality and miniaturization. Therefore, the electro-optical device itself realizes high quality and miniaturization thereof.

### Fourth Embodiment

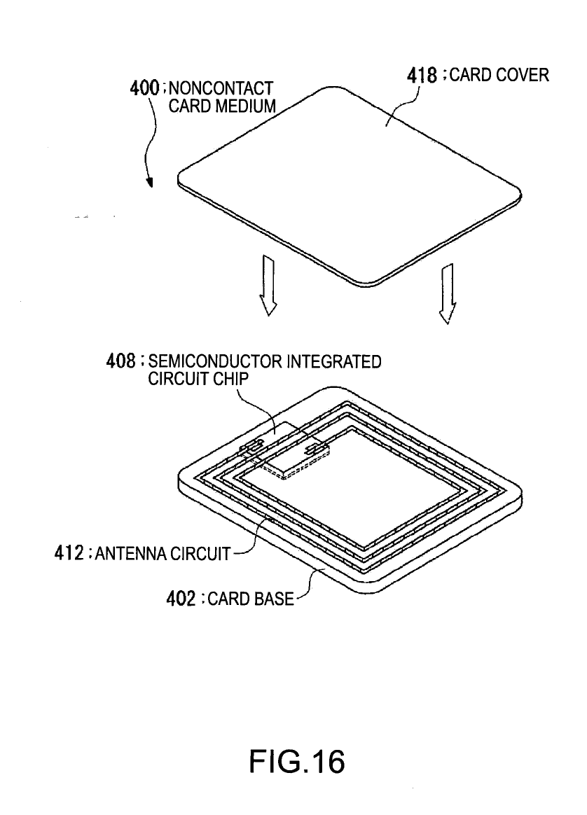

For another example other than the semiconductor device, a noncontact card medium according to a fourth embodiment will now be described. Referring to FIG. 16, this noncontact card medium (electronic apparatus) 400 of the embodiment includes a semiconductor integrated circuit chip 408 and an antenna circuit 412 housed in a case composed of a card base 402 and a card cover 418. The medium supplies electric power and/or communicates data with an outside transceiver (not shown) by using at least one of electromagnetic waves and electrostatic capacity coupling. The antenna circuit 412 is provided by the method for forming a metal wiring described in the first embodiment.

Accordingly, the noncontact card medium realizes its high quality and miniaturization.

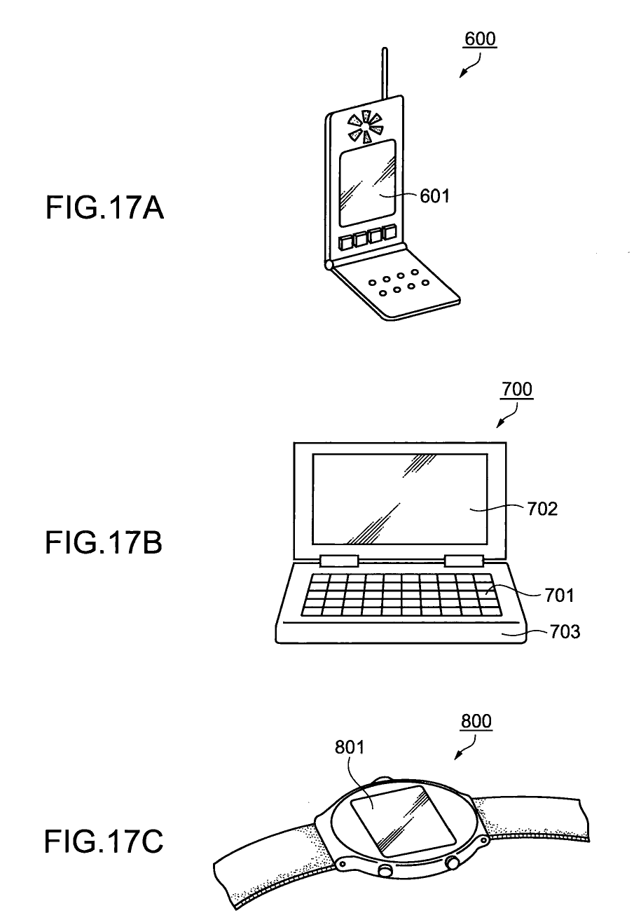

FIG. 17A is a perspective view illustrating a cellular phone that serves as an example of this electronic apparatus. Referring to FIG. 17A, this cellular phone 600 includes a liquid crystal display unit 601 having the liquid crystal display 100 described in the third embodiment.

FIG. 17B is a perspective view illustrating a portable information processing device including a word processor and a personal computer. Referring to FIG. 17B, this information processing device 700 includes an input unit 701 such as a keyboard, an information process body 703, and a liquid crystal display unit 702 having the liquid crystal display 100 of the third embodiment.

FIG. 17C is a perspective view illustrating a wristwatch electronic apparatus. Referring to FIG. 17C, this wristwatch 800 includes a liquid crystal display unit 801 having the liquid crystal display 100 of the third embodiment.

Since the electronic apparatuses shown in FIGS. 17A to 17C are provided with the liquid crystal display 100 (electro-optical device) which realizes high quality and miniaturization, the apparatuses themselves realize high quality and miniaturization thereof, as well.

The electronic apparatuses of the embodiment are provided with a liquid crystal device, but alternatively each can be provided with another electro-optical device such as an organic electroluminescent display and a plasma display.

In addition to the electronic apparatuses described above, the embodiment can be applied to various electronic apparatuses. Examples of the electronic apparatuses may include: liquid crystal projectors, personal computers (PCs) and engineering work stations (EWS) for multimedia applications, pagers, word processors, televisions, video recorders of viewfinder types or direct monitor types, electronic notebooks, electric desk calculators, car navigation systems, point-of-sale (POS) terminals, and apparatuses equipped with a touch panel.

While the preferred embodiments according to the invention are described referring to the accompanying drawings, it is understood that the invention is not limited to these examples. The shapes, combinations and the like of each component member described in the foregoing embodiments are illustrative only, and various modifications may be made based on design requirement and the like within the scope of the invention.

The first embodiment describes a case of forming the metal wiring having a triple-layer structure of the base layer, the wiring body, and the protection layer, for example, but is not so limited, the invention may be applied to a metal wiring having a double-layer structure or four- or more-layer structure.

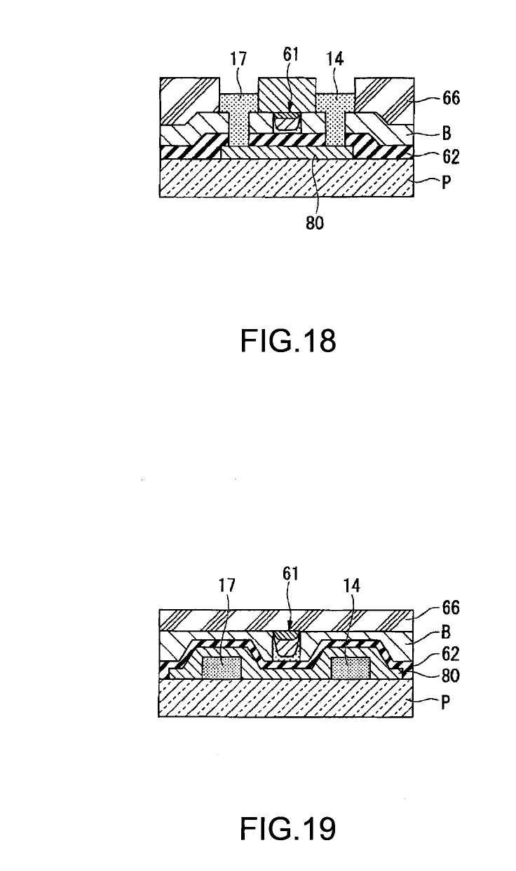

The method for forming a metal wiring of the first embodiment also can be applied when manufacturing an active matrix substrate shown in FIGS. 18 and 19. Specifically, FIG. 18 is a schematic sectional view illustrating an active matrix substrate including a transistor of a coplanar structure. In the active matrix substrate, a semiconductor layer 80 is provided on a substrate P, and the gate electrode 61 is formed on the semiconductor layer 80 with the gate insulating film 62 interposed therebetween. The bank B surrounds the gate electrode 61 so as to define the pattern of the gate electrode 61. The bank B functions as an interlayer insulating layer, as well.

The gate electrode 61 is formed by the above method for forming a metal wiring.

The bank B and the gate insulating film 62 are provided with contact holes, through which the source electrode 17 and the drain electrode 14 are formed. The source electrode 17 is coupled to a source region of the semiconductor layer 80 and the drain electrode 14 is coupled to a drain region of the semiconductor layer 80. To the drain electrode 14, a pixel electrode is coupled.

FIG. 19 is a schematic sectional view illustrating an active matrix substrate including a transistor of a stager structure. In the structure, the source electrode 17 and the drain electrode 14 are provided on the substrate P, and the semiconductor layer 80 is formed over the source electrode 17 and the drain electrode 14. On the semiconductor layer 80, the gate electrode 61 is formed with the gate insulating film 62 interposed therebetween. The bank B surrounds the gate electrode 61 so as to define the pattern of the gate electrode 61. The bank B functions as an interlayer insulating layer, as well. The gate electrode 61 is formed by the above method for forming a metal wiring.

A pixel electrode is connected to the drain electrode 14.

When manufacturing such active matrix substrates, the above method for forming a metal wiring can be applied. That is, when forming the gate electrode 61 in a region surrounded by the bank B for example, the method for forming a metal wiring of the above embodiment of the invention is used, thereby being able to form a gate electrode which has high adhesion force and expresses stable properties. Note that the method for forming a metal wiring can be applied to processes to form not only a gate electrode, but also a source electrode, a drain electrode, and a pixel electrode.

What is claimed is:

1. A device, comprising:
a substrate;
a bank provided on the substrate; and
a metal wiring in a wiring forming region of the substrate sectioned by the bank, wherein
the metal wiring includes:
a first film formed along a bottom of the wiring forming region and a side face of the bank facing the wiring forming region; and
a second film disposed on the first film.

2. The device according to claim 1, wherein the second film comprises a wiring body, and the first film comprises an intermediate layer which enhances an adhesion force between the second film and the bottom of the wiring forming region, and between the second film and the side face of the bank.

3. The device according to claim 1, further comprising a third film disposed on the second film to cover and protect the second film.

4. The device according to claim 1, wherein the side face of the bank has a lyophilic property relative to a functional liquid including a forming material of the first film, and an upper face of the bank has a lyophobic property relative to the functional liquid.

5. An electro-optical device, comprising the device according to claim 1.

6. An electronic apparatus, comprising the electro-optical device according to claim 5.

7. A method for forming a metal wiring, comprising:
imparting a lyophilic property to a bottom of a wiring forming region of a substrate which is sectioned by a bank formed on the substrate, and to a side face of the bank facing the wiring forming region;
forming a first film along the bottom of the wiring forming region and the side face of the bank facing the wiring forming region; and
disposing a second film on the first film.

8. The method for forming a metal wiring according to claim 7, wherein the second film comprises a wiring body, and the first film comprises an intermediate layer which enhances an adhesion force between the second film and the bottom of the wiring forming region, and between the second film and the side face of the bank.

9. The method for forming a metal wiring according to claim 7, further comprising: forming a third film on the second film to cover and protect the second film.

10. A method for manufacturing an active matrix substrate, comprising:
(a) forming a gate wiring on a substrate;
(b) forming a gate insulating film on the gate wiring;
(c) disposing a semiconductor layer on the gate insulating film;
(d) forming a source electrode and a drain electrode on the gate insulating film;
(e) disposing an insulating material on the source electrode and the drain electrode; and
(f) forming a pixel electrode on the insulating material,
wherein the method for forming a metal wiring according to claim 7 is used in at least one of steps (a), (d), and (f).

11. A method for manufacturing an active matrix substrate, comprising:
(a) forming a source electrode and a drain electrode on a substrate;
(b) forming a semiconductor layer on the source electrode and the drain electrode;
(c) forming a gate electrode on the semiconductor layer with a gate insulating film interposed between the gate electrode and the semiconductor layer; and
(d) forming a pixel electrode so as to be coupled to the drain electrode,
wherein the method for forming a metal wiring according to claim 7 is used in at least one of steps (a), (c), and (d).

12. A method for manufacturing an active matrix substrate, comprising:
(a) forming a semiconductor layer on a substrate;
(b) forming a gate electrode on the semiconductor layer with a gate insulating film interposed between the gate electrode and the semiconductor layer;
(c) forming a source electrode so as to be coupled to a source region of the semiconductor layer through a first contact hole formed in the gate insulating film, and a drain electrode so as to be coupled to a drain region of the semiconductor layer through a second contact hole formed in the gate insulating film; and
(d) forming a pixel electrode so as to be coupled to the drain electrode,
wherein the method for forming a metal wiring according to claim 7 is used in at least one of steps (b), (c), and (d).

13. A device comprising:
a substrate;
a bank on the substrate and defining a wiring forming region of the substrate; and
a metal wiring in the wiring forming region, the metal wiring including:
an intermediate layer directly on the wiring forming region and a side face of the bank adjacent the wiring forming region; and
a wiring body directly on the first film.

14. The device according to claim 13, further comprising a protective layer directly on the wiring body.

15. The device according to claim 13, wherein the side face of the bank further comprises:
a lyophilic portion that is lyophilic relative to a functional liquid including a forming material of the intermediate layer; and
a lyophobic portion that is lyophobic relative to the functional liquid,
wherein the lyophilic portion is located between the lyophobic portion of the bank and the wiring forming region of the substrate.

16. A method for forming a metal wiring, comprising:
forming a bank on a substrate, the bank defining a wiring forming region on the substrate;
imparting a lyophilic property to the wiring forming region of the substrate and to a first portion of the bank adjacent the wiring forming region;
disposing an intermediate layer directly on the wiring forming region and the first portion of the bank; and
disposing a wiring body directly on the intermediate layer.

17. The method for forming a metal wiring according to claim 16, further comprising forming a protective layer directly on the wiring body.

18. The method for forming a metal wiring according to claim 16, further comprising imparting a lyophobic property to a second portion of the bank separated from the wiring forming region by the first portion of the bank.
